(19) United States
(12) Patent Application Publication
(10) Pub. No.: US 2025/0324519 A1
(43) Pub. Date: Oct. 16, 2025

(54) SEMICONDUCTOR PACKAGE

(71) Applicant: LG INNOTEK CO., LTD., Seoul (KR)

(72) Inventors: Kee Han LEE, Seoul (KR); Sang Il KIM, Seoul (KR); Se Woong NA, Seoul (KR)

(73) Assignee: LG INNOTEK CO., LTD., Seoul (KR)

(21) Appl. No.: 18/870,547

(22) PCT Filed: Jun. 8, 2023
(86) PCT No.: PCT/KR2023/007849

§ 371 Date: Nov. 29, 2024

(30) Foreign Application Priority Data
Jun. 8, 2022 (KR) 10-2022-0069412

(51) Int. Cl. H05K 3/28; H01L 25/10; H01L 25/18; H05K 1/11; H05K 1/18

(52) U.S. Cl. CPC H05K 3/287; H01L 25/105; H01L 25/18; H05K 1/115; H05K 1/181; H05K 2201/09827; H05K 2201/10159; H05K 2201/10212; H05K 2203/0562; H05K 2203/1377

(57) ABSTRACT

A semiconductor package according to an embodiment comprises an insulating layer; a pad part disposed on the insulating layer; a protective layer disposed on the insulating layer and including an open region overlapping the pad part in a vertical direction, wherein a width of the open region of the protective layer in a horizontal direction satisfies a range of 10 μm to 30 μm, and a surface roughness of an upper surface of the protective layer is different from a surface roughness of an inner surface of the open region of the protective layer.

### TECHNICAL FIELD

An embodiment relates to a circuit board and a semiconductor package comprising the same.

### BACKGROUND ART

In general, a printed circuit board (PCB) is a laminated structure in which insulating layers and conductor layers are alternately laminated, and the conductor layers can be formed into a circuit pattern by patterning.

A printed circuit board such as this is equipped with a solder resist (SR) that protects a circuit formed on an outermost side of the laminate structure, prevents oxidation of the conductor layer, and also acts as an insulator when electrically connecting to a chip or other substrate mounted on the printed circuit board.

A typical solder resist forms an open region (SRO: Solder Resist Opening) that becomes an electrical connection path by combining connecting means such as solder or bumps. In addition, the open region of the solder resist requires a larger number of open regions due to the improvement of I/O (Input/Output) performance as the printed circuit board becomes high-performance and dense, and therefore a smaller bump pitch of the open region is required. At this time, a bump pitch of the open region means a distance between centers adjacent open regions.

Meanwhile, the open region (SRO) of the solder resist includes a SMD (Solder Mask Defined type) type and a NSMD (Non-Solder Mask Defined Type) type.

The SMD type is characterized in at the width of the open region (SRO) is smaller than a width of a pad exposed through the open region (SRO), and thus, at least a part of an upper surface of the pad in the SMD type is covered by the solder resist.

In addition, the NSMD type is characterized in that a width of the open region (SRO) is larger than a width of the pad exposed through the open region (SRO). Accordingly, in the NSMD type, the solder resist is disposed at a certain distance from the pad, so that both the upper surface and the side surface of the pad are exposed.

However, in a case of the SMD type, after the semiconductor package is combined with a main board, there is a problem that a solder ball is separated from the pad exposed through the open region (SRO) during a solder ball joint reliability test for a bonding strength of the solder ball. In addition, in a case of the NSMD type, there is a problem that the pad on which the solder ball is placed is separated from the circuit board. Accordingly, conventionally, the SMD type and the NSMD type are appropriately combined and applied to one circuit board.

However, in the case of a circuit board including the open region (SRO) of the conventional SMD type and the NSMD type, there is a problem that, during a process of exposing the solder resist layer, light is not sufficiently transmitted to a lower region of an exposure region of the solder resist layer, and thus, the lower region of the exposure region is not sufficiently cured. In addition, when a development process is performed in a state where the lower region of the exposure region is not sufficiently cured, there is a problem that an undercut occurs in which the lower region of the exposure region is removed together. Furthermore, as a thickness of the solder resist layer increases, a width of the undercut increases, and accordingly, there is a problem that the reliability of the circuit board decreases.

In addition, when the solder resist layer is exposed to form an open region, a size of the open region is determined according to an exposure resolution of the solder resist layer. However, the size of the open region that can be formed in the solder resist layer is approximately 70 μm for general resolution, and up to 50 μm for high resolution.

However, a data processing amount is rapidly increasing due to technological advancement. In response to this, a number of terminals of a semiconductor device mounted in a semiconductor package is increasing. Therefore, a new structure capable of reducing a size of the open region that can be formed on the solder resist layer while removing the undercut is required.

### DISCLOSURE

### Technical Problem

An embodiment provides a circuit board capable of reducing a size of an open region that may be formed in a protective layer and a semiconductor package including the same.

In addition, the embodiment provides a circuit board capable of removing a undercut formed at a sidewall of an open region of the protective layer and a semiconductor package including the same.

In addition, the embodiment provides a circuit board capable of reducing a tolerance (SRR) between a center of an open region of a protective layer and a center of a pad and a semiconductor package including the same.

In addition, the embodiment provides a circuit board with improved electrical and mechanical characteristics and a semiconductor package including the same.

In addition, the embodiment provides a circuit board capable of improving bonding strength with a molding layer and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A semiconductor package according to an embodiment comprises an insulating layer; a pad part disposed on the insulating layer; a protective layer disposed on the insulating layer and including an open region overlapping the pad part in a vertical direction, wherein a width of the open region of the protective layer in a horizontal direction satisfies a range of 10 μm to 30 μm, and a surface roughness of an upper surface of the protective layer is different from a surface roughness of an inner surface of the open region of the protective layer.

In addition, the surface roughness of the upper surface of the protective layer is greater than the surface roughness of the inner surface of the open region of the protective layer.

In addition, the protective layer includes a resin and a plurality of fillers dispersed in the resin, and at least one of the plurality of fillers is exposed through the upper surface of the protective layer.

In addition, the pad part includes a first pad, the open region includes a first open region partially overlapping the first pad in the vertical direction, and a width of the first open region is smaller than a width of the first pad.

In addition, the pad includes a second pad, open region includes a second open region completely overlapping the second pad in the vertical direction, and a width of the second open region is larger than a width of the second pad.

In addition, the inner surface of the open region has a slope in which a width of the open region decreases from the upper surface of the protective layer toward a lower surface of the protective layer.

In addition, the inner surface of the open region has a slope in which a width of the open region increases from the upper surface of the protective layer toward a lower surface of the protective layer.

In addition, a difference between a maximum width and a minimum width in the horizontal direction along a thickness direction of the open region is 3 μm or less.

In addition, a center of the open region and a center of the pad part are misaligned in the vertical direction.

In addition, a width in the horizontal direction between the center of the open region and the center of the pad part is 10 μm or less.

### Advantageous Effects

The embodiment includes an insulating layer, a pad disposed on the insulating layer, and a protective layer disposed on the insulating layer and including an open region overlapping the pad in a vertical direction.

In this case, a width of the open region of the protective layer of the embodiment is 30 μm or less. For example, the width of the open region of the protective layer of the embodiment may satisfy a range of 10 μm to 30 μm, 12 μm to 28 μm, or 13 μm to 25 μm.

Furthermore, the open region of the protective layer of the embodiment has little change in width toward a thickness direction. For example, in an entire region in a thickness direction of the open region of the embodiment, the difference between a width of a region having a maximum width and a region having a minimum width may be 3 μm or less, 2.5 μm or less, 2 μm or less, 1.5 μm or less, 1 μm or less, or 0.5 μm or less. That is, in an embodiment, an undercut at a lower end of the inner surface of the open region of the protective layer may be removed, or a horizontal distance of an undercut may be significantly reduced compared to a comparative example.

This is because the open region of the protective layer is not formed by exposing and developing the protective layer, but a separate resist pattern is used. That is, in an embodiment, the protective layer is disposed in a state in which a resist pattern is formed using a photosensitive film. Accordingly, an open region corresponding to the resist pattern may be formed in the protective layer. In this case, the photosensitive film does not include a filler therein. Accordingly, in general, a minimum size of a resist pattern formed by exposing and developing the photosensitive film is smaller than that of a resist pattern formed by exposing and developing a solder resist containing a filler.

Accordingly, an embodiment does not expose and develop a protective layer such as a solder resist, but rather exposes and develops a photosensitive film capable of implementing a relatively fine pattern to form a resist pattern. Then, an embodiment forms an open region in the protective layer by using the resist pattern. Accordingly, an embodiment may reduce a size of the open region formed on the protective layer compared to a comparative example, thereby improving the circuit integration.

Furthermore, since the embodiment does not expose and develop the protective layer, and it is possible to remove undercuts that may be formed at the inner surface of the open region of the protective layer. Accordingly, the embodiment may further reduce a spacing between circuit pattern layers.

Meanwhile, in the embodiment, in a state in which the resist pattern is disposed, a thickness of the protective layer is made larger than that of the resist pattern and then a process of thinning the protective layer is performed. That is, in the embodiment, the protective layer may have a target thickness through the thinning. In this case, a process of applying the protective layer to have a target thickness may be performed without proceeding with the thinning process. However, if the thinning process is not performed, there is a problem that a thickness deviation of the protective layer increases, and accordingly, a flatness of the protective layer decreases.

On the other hand, since the embodiment performs the thinning process, the flatness of the protective layer may be improved. Accordingly, the embodiment may improve overall physical reliability and electrical reliability of the circuit board and the semiconductor package.

In addition, the filler may be entirely exposed on the upper surface of the protective layer of the embodiment. In addition, the exposed filler increases a surface roughness of the upper surface of the protective layer. Accordingly, the embodiment may increase a bonding area between the protective layer and the molding layer in a molding process after the semiconductor device is mounted on a circuit board, thereby improving bonding strength. Accordingly, the embodiment may further improve product reliability.

Meanwhile, in an embodiment, since the protective layer is not exposed and developed, a photo initiator is not required in the protective layer. For example, a general solder resist contains a photo initiator for exposure and development. In this case, the photo initiator acts as a factor that deteriorates physical and electrical characteristics of the circuit board. In this case, an embodiment may improve physical and electrical characteristics of the circuit board since a photo initiator is not included in the protective layer.

Furthermore, since the embodiment does not include a photo initiator in the protective layer, a type of insulating layer that can be used as the protective layer can be expanded, and furthermore, an unit price required for the development of the protective layer can be reduced.

Furthermore, an embodiment may significantly reduce a tolerance between a center of the open region of the protective layer and a center of the pad compared to the comparative example. Accordingly, an embodiment may improve mount-ability of a semiconductor device, thereby improving the physical reliability and electrical reliability of the circuit board and the semiconductor package.

### DESCRIPTION OF DRAWINGS

FIG. 1 is a cross-sectional view showing a circuit board according to a comparative example.

FIG. 2 is a cross-sectional view showing a circuit board according to a first embodiment.

FIG. 3 is a cross-sectional view showing a circuit pattern layer of FIG. 2 in more detail.

FIG. 4 is a scanning electron microscope image showing an upper surface of a first protective layer of FIG. 3.

FIG. 5 is a scanning electron microscope image showing a sidewall of an open region of a first protective layer of FIG. 3.

FIG. 6 is a view showing a resist pattern used to form an open region of a first protective layer of an embodiment.

FIG. 7 is a plan view explaining a tolerance (SRR: Solder Resist Registration) according to a comparative example.

FIG. 8 is a drawing explaining a tolerance according to a first embodiment.

FIG. 9 is a cross-sectional view showing a circuit board according to a second embodiment.

FIG. 10 is a cross-sectional view showing a circuit board according to a third embodiment.

FIG. 11 is a cross-sectional view showing a semiconductor package according to the embodiment.

FIGS. 12 to 19 are cross-sectional views showing a method for manufacturing a circuit board according to an embodiment in order of processes.

### BEST MODE

Hereinafter, the embodiment disclosed in the present specification will be described in detail with reference to the accompanying drawings, but the same or similar components are designated by the same reference numerals regardless of drawing numbers, and repeated description thereof will be omitted. The component suffixes “module” and “part” used in the following description are given or mixed together only considering the ease of creating the specification, and have no meanings or roles that are distinguished from each other by themselves. In addition, in describing the embodiments disclosed in the present specification, when it is determined that detailed descriptions of a related well-known art unnecessarily obscure gist of the embodiments disclosed in the present specification, the detailed description thereof will be omitted. Further, the accompanying drawings are merely for facilitating understanding of the embodiments disclosed in the present specification, the technological scope disclosed in the present specification is not limited by the accompanying drawings, and it should be understood as including all modifications, equivalents and alternatives that fall within the spirit and scope of the present invention.

It will be understood that, although the terms “first,” “second,” etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

As used herein, the singular forms “a,” “an” and “the” are intended to include the plural forms as well, unless the context clearly indicates otherwise.

It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Hereinafter, an embodiment of the present invention will be described in detail with reference to the attached drawings.

### COMPARATIVE EXAMPLE

Before explaining the embodiments of the present invention, the problems of comparative examples will be explained.

FIG. 1 is a cross-sectional view of a circuit board according to a comparative example.

Referring to FIG. 1, the circuit board of the comparative example includes an insulating layer 10, a circuit pattern layer, and a protective layer 30.

The circuit pattern layer is disposed on the upper surface of the insulating layer 10.

The circuit pattern layer includes a plurality of circuit patterns spaced apart from each other. The circuit patterns include pads and traces.

For example, the circuit pattern layer includes a first pad 21, a second pad 22, and a trace 23.

The protective layer 30 includes a plurality of open regions.

For example, the protective layer 30 includes a first open region 31 vertically overlapping the first pad 21.

The first open region 31 partially opens the upper surface of the first pad 21. For example, the first open region 31 is an SMD type open region.

A width (w1) of the first open region 31 exceeds at least 50 μm depending on an exposure resolution (e.g., high resolution) of the protective layer 30. Specifically, the width (w1) of the first open region 31 exceeds at least 70 μm depending on an exposure resolution (e.g., general resolution) of the protective layer 30. Therefore, the width of the first pad 21 vertically overlapping the first open region 31 exceeds 70 μm, which is larger than the width (w1) of the first open region 31. For example, the width of the first pad 21 exceeds 90 μm, which is larger than the width (w1) of the first open region 31. This is in consideration of a process deviation in a process of forming the first open region 31.

As described above, the first open region 31 is at least 50 μm or more than 70 μm, and accordingly, the width of the first pad 21 is more than 70 μm or more than 90 μm. Accordingly, the comparative example has a limitation in reducing a spacing between a plurality of first pads. That is, the comparative example has a limitation in miniaturizing the width (w1) of the first open region 31, and further has a limitation in miniaturizing the width of the first pad 21.

The protective layer 30 includes a second open region 32 that vertically overlaps the second pad 22. The second open region 32 entirely opens an upper surface of the second pad 22. That is, the second open region 32 is an NSMD type open region.

The width (w2) of the second open region 32 exceeds 50 μm or 70 μm depending on the exposure resolution of the protective layer 30. That is, the protective layer 30 has a limit in minimizing a width (w2) of the second open region 32.

Furthermore, the protective layer 30 forms the first open region 31 and the second open region 32 by performing an exposure and curing process. At this time, in a process of exposing and curing the protective layer 30, there is a problem that a lower region of the protective layer 30 is not completely cured. In addition, if the curing is not completely performed, in a process of forming the second open region 32, there is a problem that an undercut 33 is formed at a lower region of a side wall of the second open region 32.

At this time, a horizontal distance (w3) of the undercut 33 of the comparative example exceeds 15 μm or 20 μm. The horizontal distance (w3) of the undercut 33 means a horizontal distance from an innermost end to an outermost end in a lower region of the side wall of the second open region 32.

At this time, the circuit pattern layer includes a trace 23 disposed adjacent to the second pad 22. In addition, the comparative example must consider the horizontal distance (w3) of the undercut 33 when disposing the trace 23. That is, if the comparative example does not consider the horizontal distance (w3) of the undercut 33, a side of the trace 23 may be exposed through the undercut 33. In this case, a solder ball disposed on the second pad 22 spreads to the undercut 33, and thus, a circuit short problem occurs due to contact with the trace 23. Therefore, in the comparative example, a distance between the second pad 22 and the trace 23 is determined by considering the width (w2) of the second open region 32 and the horizontal distance (w3) of the undercut 33. Therefore, the comparative example has a problem in that the distance increases and the circuit integration decreases accordingly.

In addition, as the performance of electric/electronic products has been improved recently, technologies for attaching a larger number of semiconductor devices to a limited-sized substrate have been studied, and accordingly, miniaturization of the circuit pattern is required. In a case of a semiconductor package using a circuit board of the comparative example, a minimum width of the open region that can be formed in the protective layer 30 and the horizontal distance of the undercut must be considered, and thus, there is a limit to miniaturizing the circuit pattern.

Furthermore, recently, functions processed in logic chips such as application processors (APs) have been increasing. Accordingly, it has become difficult to implement all functions in one logic chip. Therefore, a space for mounting multiple logic chips is required on the circuit board. However, it is difficult to mount multiple logic chips with different functions in a limited space using the circuit board of the comparative example.

The embodiment is intended to solve this problem, and significantly reduces the width of the open region that can be formed in the protective layer compared to the comparative example. In addition, the embodiment minimizes a horizontal distance of the undercut formed at the sidewall of the open region of the protective layer, or removes the undercut. In addition, the embodiment can reduce a tolerance (SRR: Solder Resist Registration) between a center of the open region of the protective layer and a center of the pad. In addition, the embodiment can improve the electrical and mechanical characteristics while improving the bonding strength with the molding layer.

### Electronic Device

Before describing the embodiment, an electronic device including a semiconductor package of the embodiment will be briefly described. The electronic device includes a main board (not shown). The main board can be physically and/or electrically connected to various components. For example, the main board can be connected to the semiconductor package of the embodiment. Various semiconductor devices can be mounted in the semiconductor package.

The semiconductor devices can include active devices and/or passive devices. The active devices can be semiconductor chips in the form of integrated circuits (ICs) in which hundreds to millions of devices are integrated into one chip. The semiconductor chips can be logic chips, memory chips, etc. The logic chips can be central processors (CPUs), graphics processors (GPUs), etc. For example, the logic chip may be an AP including at least one of a central processor (CPU), a graphics processor (GPU), a digital signal processor, an encryption processor, a microprocessor, a microcontroller, or an analog-to-digital converter, an application- specific IC (ASIC), or a chip set including a specific combination of the above.

The memory chip may be a stacked memory such as HBM. In addition, the memory chip may include a memory chip such as a volatile memory (e.g., DRAM), a non-volatile memory (e.g., ROM), a flash memory, etc.

Meanwhile, a product group to which the semiconductor package of the embodiment is applied may be any one of a CSP (Chip Scale Package), an FC-CSP (Flip Chip-Chip Scale Package), an FC-BGA (Flip Chip Ball Grid Array), a POP (Package On Package), and a SIP (System In Package), but is not limited thereto.

In addition, the electronic device may be a smart phone, a personal digital assistant, a digital video camera, a digital still camera, a network system, a computer, a monitor, a tablet, a laptop, a netbook, a television, a video game, a smart watch, an automotive, etc. However, the embodiment is not limited thereto, and it may be any other electronic device that processes data.

### Circuit Board

Hereinafter, a circuit board of an embodiment will be described.

A circuit board means a board before a semiconductor device or chip is mounted.

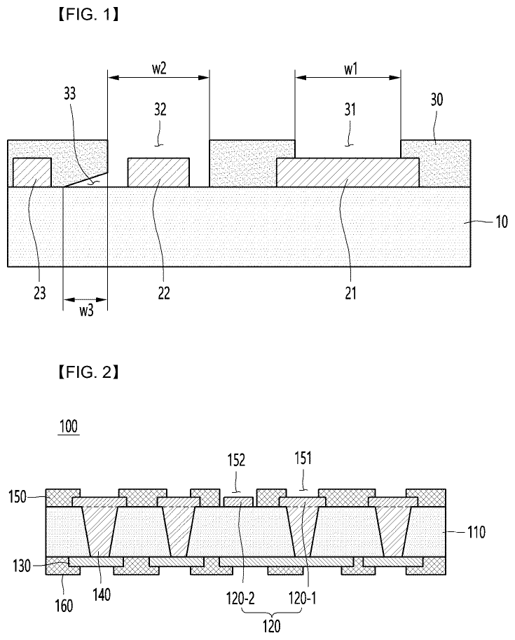

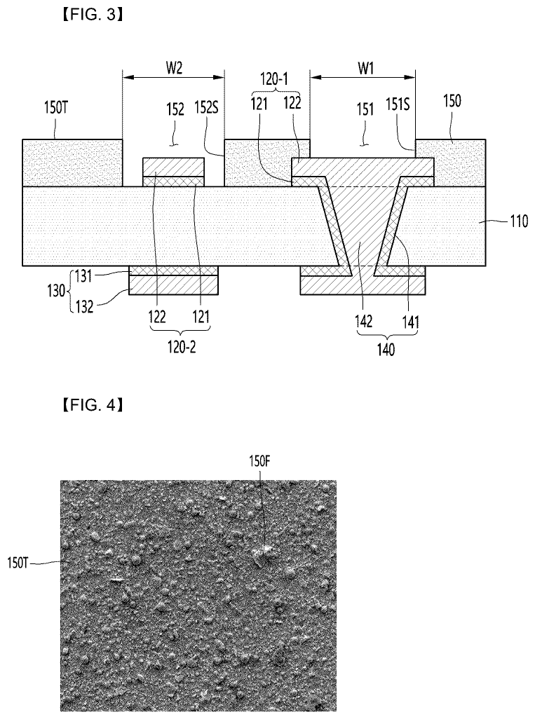

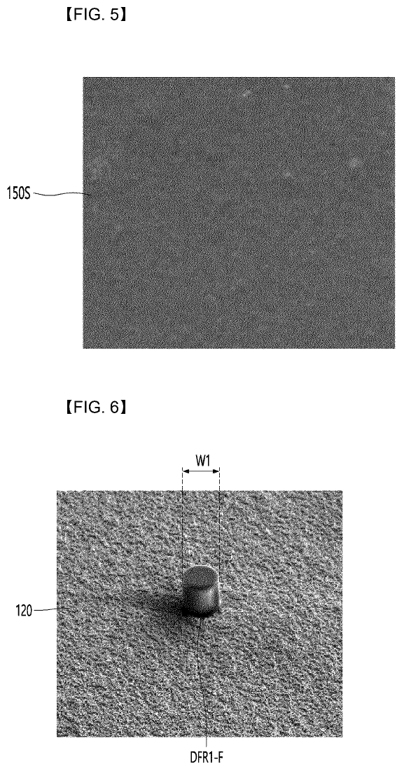

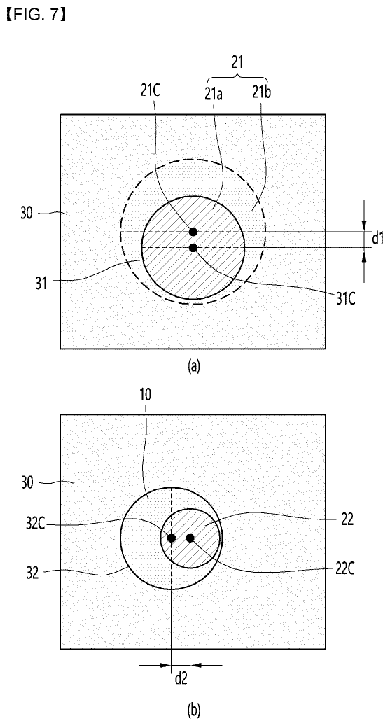

FIG. 2 is a cross-sectional view showing a circuit board according to a first embodiment, FIG. 3 is a cross-sectional view showing a circuit pattern layer of FIG. 2 in more detail, FIG. 4 is a scanning electron microscope image showing an upper surface of a first protective layer of FIG. 3, FIG. 5 is a scanning electron microscope image showing a sidewall of an open region of a first protective layer of FIG. 3, and FIG. 6 is a view showing a resist pattern used to form an open region of a first protective layer of an embodiment.

Hereinafter, the circuit board according to the first embodiment will be specifically described with reference to FIGS. 2 to 6.

The circuit board of the first embodiment provides a mounting space capable of mounting at least one semiconductor device.

For example, the circuit board of the first embodiment may provide a mounting space for mounting one semiconductor device, or alternatively, may provide multiple mounting spaces for mounting two or more semiconductor devices.

In addition, one logic chip may be mounted on the circuit board of the first embodiment. In addition, the circuit board of the first embodiment may be mounted with at least two logic chips of different types. In addition, the circuit board of the first embodiment may be mounted with at least one logic chip and at least one memory chip.

The circuit board 100 of the first embodiment includes an insulating layer 110. The insulating layer 110 may have one or more layers. Preferably, the insulating layer 110 may have a multilayer structure. In this case, the insulating layer 110 is illustrated as being composed of one layer in the drawing, but is not limited thereto. For example, the insulating layer 110 may include a plurality of insulating layers having a vertically laminated structure.

Hereinafter, for convenience of explanation, the insulating layer 110 is illustrated as one layer.

The insulating layer 110 may be rigid or flexible.

For example, the insulating layer 110 may include a prepreg. For example, the insulating layer 110 may be a prepreg in which glass fibers are impregnated in a resin. The resin may be an epoxy resin, but is not limited thereto.

In addition, the insulating layer 110 may include chemically strengthened/semi-strengthened glass such as soda lime glass or aluminosilicate glass. For example, the insulating layer 110 may include a strengthened or flexible plastic such as polyimide (PI), polyethylene terephthalate (PET), propylene glycol (PPG), or polycarbonate (PC). For example, the insulating layer 110 may include sapphire. For example, the insulating layer 110 may include an optically isotropic film. For example, the insulating layer 110 may include COC (Cyclic Olefin Copolymer), COP (Cyclic Olefin Polymer), photo isotropic polycarbonate (PC), or photo isotropic polymethyl methacrylate (PMMA). For example, the insulating layer 110 may be formed of a material including an inorganic filler and an insulating resin. For example, the insulating layer 110 may have a structure in which an inorganic filler such as silica or alumina is disposed in a thermosetting resin or a thermoplastic resin. For example, the insulating layer 110 may use ABF (Ajinomoto Build-up Film), FR-4, BT (Bismaleimide Triazine), PID (Photo Imageable Dielectric resin), BT, etc. For example, the insulating layer 110 may include RCC (Resin coated copper).

The insulating layer 110 may have a thickness in a range of 10 μm to 60 μm. For example, when the insulating layer 110 includes multiple layers, a thickness of each of the multiple layers may satisfy a range of 10 μm to 60 μm. Preferably, the insulating layer 110 may satisfy a thickness in a range of 15 μm to 55 μm. More preferably, the insulating layer 110 may satisfy a thickness in a range of 18 μm to 52 μm.

The thickness of the insulating layer 110 may mean a vertical distance between multiple circuit pattern layers disposed adjacent to each other in a thickness direction. For example, the thickness of the insulating layer 110 may mean a vertical distance between the first circuit pattern layer and the second circuit pattern layer 130. For example, the thickness of the insulating layer 110 may mean a vertical distance between the lower surface of the first circuit pattern layer 120 and the upper surface of the second circuit pattern layer 130.

If the thickness of the insulating layer 110 is less than 10 μm, warpage characteristics of the circuit board 100 may deteriorate. For example, if the thickness of the insulating layer 110 is less than 10 μm, the first circuit pattern layer 120 and the second circuit pattern layer 130 disposed on the surface of the insulating layer 110 are not stably protected, and thus, electrical reliability and/or physical reliability problems may occur. In addition, if the thickness of the insulating layer 110 is less than 10 μm, processability in a process of forming the first circuit pattern layer 120 or the second circuit pattern layer 130 on the insulating layer 110 may deteriorate.

In addition, if the thickness of the insulating layer 110 exceeds 60 μm, an overall thickness of the circuit board 100 may increase, and thus, a thickness of the semiconductor package may increase. In addition, if the thickness of the insulating layer 110 exceeds 60 μm, it may be difficult to miniaturize the first circuit pattern layer and/or the second circuit pattern layer 130. For example, if the thickness of the insulating layer 110 exceeds 60 μm, it may be difficult to form a width of the first circuit pattern layer and/or the second circuit pattern layer 130 and a spacing between adjacent patterns to 12 μm or less, 10 μm or less, 8 μm or less, or 6 μm or less. In addition, if it is difficult to miniaturize the first circuit pattern layer and/or the second circuit pattern layer 130, the circuit integration may be reduced, and accordingly, a signal transmission distance may increase, which may increase the signal transmission loss.

The circuit board 100 of the first embodiment includes a circuit pattern layer disposed on the insulating layer 110.

For example, the circuit board 100 of the first embodiment includes a first circuit pattern layer 120 disposed on an upper surface of the insulating layer 110. In addition, the circuit board 100 includes a second circuit pattern layer 130 disposed on a lower surface of the insulating layer 110.

The first circuit pattern layer 120 may be divided into a plurality of circuit patterns according to position or function. For example, the first circuit pattern layer 120 may include a first pad 120-1 and a second pad 120-2. At least one of the first pad 120-1 and the second pad 120-2 may be formed to correspond to a mounting region of a semiconductor device. For example, at least one of the first pad 120-1 and the second pad 120-2 may mean a mounting pad connected to a terminal of a semiconductor device. In contrast, at least one of the first pad 120-1 and the second pad 120-2 may mean a terminal pad that is coupled with an external substrate. For example, at least one of the first pad 120-1 and the second pad 120-2 may mean a terminal pad that is coupled with an interposer or a main board of an electronic device.

At this time, as functions provided by semiconductor devices have increased recently, a number of terminals provided in the semiconductor devices or a number of semiconductor devices mounted has increased.

Therefore, miniaturization of the first pad 120-1 and the second pad 120-2 of the first circuit pattern layer 120 is required. However, in the comparative example, there was a limit to miniaturizing the first circuit pattern layer 120 due to the size limit of the open region of the protective layer and the undercut. At this time, the embodiment minimizes a size of the open region of the protective layer and a horizontal distance of the undercut so that the first circuit pattern layer 120 can be miniaturized. This can be achieved by a method of forming an open region in the protective layer described below.

Meanwhile, when the insulating layer 110 of the circuit board 100 includes a plurality of layers, the first circuit pattern layer 120 can be disposed on an upper surface of an insulating layer disposed on an uppermost side among the plurality of layers of the insulating layer 110, and the second circuit pattern layer 130 can be disposed on a lower surface of an insulating layer disposed on a lowermost side among the plurality of layers of the insulating layer 110. For example, the first circuit pattern layer 120 and the second circuit pattern layer 130 may refer to outer circuit pattern layers, but are not limited thereto.

Meanwhile, when the insulating layer 110 includes a plurality of layers, an additional inner circuit pattern layer may be disposed between the plurality of layers.

The first circuit pattern layer 120 and the second circuit pattern layer 130 may each have a plurality of layer structures.

The first circuit pattern layer 120 may include a first metal layer 121 and a second metal layer 122. That is, each of the first pad 120-1 and the second pad 120-2 of the first circuit pattern layer 120 may include a first metal layer 121 and a second metal layer 122.

The first metal layer 121 of the first circuit pattern layer 120 may be disposed on an upper surface of the insulating layer 110. For example, the first metal layer 121 of the first circuit pattern layer 120 may protrude above the upper surface of the insulating layer 110.

The first metal layer 121 of the first circuit pattern layer 120 may be formed by an electroless plating method. For example, the first metal layer 121 may be formed by a chemical copper plating method, but is not limited thereto. For example, the first metal layer 121 may also be formed by a sputtering method.

A thickness of the first metal layer 121 of the first circuit pattern layer 120 may satisfy a range of 0.2 μm to 3.0 μm. Preferably, the thickness of the first metal layer 121 of the first circuit pattern layer 120 may satisfy a range of 0.3 μm to 2.8 μm. More preferably, the thickness of the first metal layer 121 of the first circuit pattern layer 120 can satisfy a range of 0.5 μm to 2.5 μm.

If the thickness of the first metal layer 121 of the first circuit pattern layer 120 is less than 0.2 μm, the first metal layer 121 of the first circuit pattern layer 120 may not function as a seed layer. If the thickness of the first metal layer 121 of the first circuit pattern layer 120 is less than 0.2 μm, it may be difficult to form a first metal layer 121 having an uniform thickness on the upper surface of the insulating layer 110.

If the thickness of the first metal layer 121 of the first circuit pattern layer 120 exceeds 3.0 μm, a process time for forming the first metal layer 121 of the first circuit pattern layer 120 may increase, and thus the yield may decrease. In addition, if the thickness of the first metal layer 121 of the first circuit pattern layer 120 exceeds 3.0 μm, an etching time of the first metal layer 121 in a process of forming the first circuit pattern layer 120 may increase. In addition, if the thickness of the first metal layer 121 of the first circuit pattern layer 120 exceeds 3.0 μm, deformation of the second metal layer 122 of the first circuit pattern layer 120 may occur during etching of the first metal layer 121 of the first circuit pattern layer 120. Here, the deformation of the second metal layer 122 of the first circuit pattern layer 120 may mean that a difference between a width of an upper surface and a width of a lower surface of the second metal layer 122 increases as a side of the second metal layer 122 is also etched during the etching of the first metal layer 121. For example, the deformation of the second metal layer 122 of the first circuit pattern layer 120 may mean that a shape of a vertical cross-section of the second metal layer 122 changes from a square to a trapezoidal shape.

In addition, if the thickness of the first metal layer 121 of the first circuit pattern layer 120 exceeds 3.0 μm, the etching amount in a process of etching the first metal layer 121 increases, and accordingly, a depth of a recess (e.g., undercut) formed at a side of the first metal layer 121 and a side of the second metal layer 122 may increase. For example, if the etching amount in the etching process of the first metal layer 121 increases, a difference between a width of the first metal layer 121 and a width of the second metal layer 122 may increase. In addition, when the difference between the width of the first metal layer 121 and the width of the second metal layer 122 increases, electrical characteristics may deteriorate due to increased signal transmission loss. In addition, when the difference between the width of the first metal layer 121 and the width of the second metal layer 122 increases, dendrites may be formed by electromigration, thereby deteriorating the electrical characteristics and/or physical characteristics of the first circuit pattern layer 120.

The second metal layer 122 of the first circuit pattern layer 120 may be an electroplating layer formed by electroplating the first metal layer 121 with a seed layer. The second metal layer 122 of the first circuit pattern layer 120 may be formed on the first metal layer 121 with a certain thickness. The second metal layer 122 of the first circuit pattern layer 120 may include the same metal as the first metal layer 121 of the first circuit pattern layer 120, but is not limited thereto. For example, the first metal layer 121 and the second metal layer 122 of the first circuit pattern layer 120 may each include copper.

A thickness of the second metal layer 122 of the first circuit pattern layer 120 may be greater than the thickness of the first metal layer 121 of the first circuit pattern layer 120.

A thickness of the second metal layer 122 of the first circuit pattern layer 120 may satisfy a range of 3.5 μm to 25 μm. Preferably, the thickness of the second metal layer 122 of the first circuit pattern layer 120 may satisfy a range of 4.0 μm to 23 μm. More preferably, the thickness of the second metal layer 122 of the first circuit pattern layer 120 may satisfy a range of 4.5 μm to 22 μm.

If the thickness of the second metal layer 122 of the first circuit pattern layer 120 is less than 3.5 μm, the second metal layer 122 may also be etched during the etching process of the first metal layer 121. If the thickness of the second metal layer 122 of the first circuit pattern layer 120 is less than 3.5 μm, an allowable current of a signal transmitted through the first circuit pattern layer may decrease, and thus the electrical characteristics may deteriorate. If the thickness of the second metal layer 122 of the first circuit pattern layer 120 exceeds 25 μm, it may be difficult to miniaturize the first circuit pattern layer 120. For example, if the thickness of the second metal layer 122 of the first circuit pattern layer 120 exceeds 25 μm, a width and a spacing of patterns constituting the first circuit pattern layer 120 may not satisfy the required conditions. Accordingly, the circuit integration may be reduced or the volume of the circuit board and the semiconductor package may be increased.

Meanwhile, the second circuit pattern layer 130 of the circuit board 100 of the first embodiment may include a first metal layer 131 and a second metal layer 132 corresponding to the first circuit pattern layer 120. The first metal layer 131 of the second circuit pattern layer 130 of the circuit board 100 of the first embodiment corresponds to the first metal layer 121 of the first circuit pattern layer 120. In addition, the second metal layer 132 of the second circuit pattern layer 130 of the circuit board 100 of the first embodiment corresponds to the second metal layer 122 of the first circuit pattern layer 120. Accordingly, the second circuit pattern layer 120 of the circuit board 100 of the first embodiment may include characteristics of the first circuit pattern layer 120 described above. Therefore, a detailed description of the second circuit pattern layer 130 of the first embodiment is omitted.

The circuit board 100 of the first embodiment may include a through electrode 140. The through electrode 140 may penetrate the insulating layer 110. Preferably, the through electrode 140 may penetrate the insulating layer 110 to electrically connect the first circuit pattern layer 120 and the second circuit pattern layer 130. At this time, when the circuit board 100 has a multi-layer structure, the through electrode 140 may be vertically spaced apart from each other and electrically connect the adjacent circuit pattern layers.

The through electrode 140 can be formed by filling an inside of a through hole penetrating the insulating layer 110 with a conductive material.

The through hole can be formed by any one of mechanical, laser, and chemical processing methods. When the through hole is formed by mechanical processing, methods such as milling, drilling, and routing can be used. In addition, when the through hole is formed by laser processing, a UV or CO2 laser method can be used. In addition, when the through hole is formed by chemical processing, a chemical containing amino silane, ketones, etc. can be used. However, the embodiment is not limited thereto.

For example, a method for forming an open region provided in the first protective layer 150 of the embodiment may be applied to form a through hole for disposing a through electrode 140. Therefore, there may be little change in the width of the through electrode 140 from an upper surface of the through electrode 140 to a lower surface of the through electrode 140. For example, a width of an upper surface of the through electrode 140 may be the same as a width of a lower surface of the through electrode 140.

The through electrode 140 includes a plurality of metal layers.

The through electrode 140 includes a first metal layer 141 and a second metal layer 142. The first metal layer 141 of the through electrode 140 may correspond to the first metal layer 141 of the first circuit pattern layer 120. In addition, the second metal layer 142 of the through electrode 140 may correspond to the second metal layer 122 of the first circuit pattern layer 120. Accordingly, a detailed description of the first metal layer 141 and the second metal layer 142 of the through electrode 140 is omitted.

Meanwhile, in the above, the first circuit pattern layer 120 and the second circuit pattern layer 130 of the embodiment are described as including the first metal layer and the second metal layer by being manufactured by a SAP process, but this is not limited thereto.

For example, the first circuit pattern layer 120 and the second circuit pattern layer 130 may be manufactured by a MSAP process. Therefore, each of the first circuit pattern layer 120 and the second circuit pattern layer 130 may additionally have a third metal layer disposed between the first metal layer and the insulating layer. The third metal layer may refer to a copper layer attached during lamination of the insulating layer, but is not limited thereto.

Meanwhile, the circuit board 100 of the first embodiment may include a protective layer.

For example, the circuit board 100 may include a first protective layer 150 disposed on an insulating layer 110. For example, the circuit board 100 may include a second protective layer 160 disposed under the insulating layer 110.

The first protective layer 150 and the second protective layer 160 may be a resist layer. Preferably, the first protective layer 150 and the second protective layer 160 may be a solder resist layer containing an organic polymer material. As an example, the first protective layer 150 and the second protective layer 160 may include an epoxy acrylate series resin. In detail, the first protective layer 150 and the second protective layer 160 may include a resin, a curing agent, a pigment, a solvent, a filler, an additive, an acrylic monomer, etc.

A thickness of each of the first protective layer 150 and the second protective layer 160 may be greater than the thickness of each of the first circuit pattern layer 120 and the second circuit pattern layer 130.

In other words, a thickness of the first protective layer 150 may be greater than the thickness of the first circuit pattern layer. In addition, a thickness of the second protective layer 160 may be greater than the thickness of the second circuit pattern layer 130.

The thickness of the first protective layer 150 may mean a vertical distance from a lower surface of the first protective layer 150 to an upper surface of the first protective layer 150. For example, the first protective layer 150 is disposed on the upper surface of the insulating layer 110. Accordingly, the thickness of the first protective layer 150 may mean a vertical distance from an upper surface of the insulating layer 110 to an upper surface of the first protective layer 150.

The thickness of the first protective layer 150 may satisfy a range of 6.7 μm to 35.0 μm. Preferably, the thickness of the first protective layer 150 may satisfy a range of 7.3 μm to 32 μm. More preferably, the thickness of the first protective layer 150 may satisfy a range of 8.0 μm to 30 μm.

If the thickness of the first protective layer 150 exceeds 30 μm, a thickness of the circuit board and a thickness of the semiconductor package may increase. In addition, if the thickness of the first protective layer 150 is less than 6.7 μm, the first circuit pattern layer may not be stably protected, and thus, electrical reliability or physical reliability may be deteriorated.

In addition, the second protective layer 160 may have a thickness corresponding to the thickness of the first protective layer 150, but is not limited thereto.

Meanwhile, the first protective layer 150 includes at least one open region. In addition, the second protective layer 160 includes at least one open region. At this time, a width of the open region formed in the first protective layer 150 and the second protective layer 160 of the embodiment may be smaller than a width of the open region of the comparative example. This can be achieved by forming the open region of the first protective layer 150 and the second protective layer 160 using a separate resist pattern, rather than forming the open region by exposing and developing the first protective layer 150 and the second protective layer 160.

Hereinafter, the open region formed in the first protective layer 150 will be described in detail. However, a description of an open region formed in the second protective layer 160 is omitted below. For example, an open region formed in the second protective layer 160 may have a structure corresponding to the open region formed in the first protective layer 150 described below.

The first protective layer 150 includes an open region. The open region may be in a form of a through hole penetrating the upper surface and the lower surface of the first protective layer 150.

The first protective layer 150 includes a first open region 151. For example, the first protective layer 150 may include a first open region 151 vertically overlapping the first pad 120-1 of the first circuit pattern layer 120.

At this time, the first open region 151 of the first protective layer 150 may partially overlap the upper surface of the first pad 120-1 in a vertical direction. For example, the first open region 151 of the first protective layer 150 may be an SMD type open region.

That is, a width (W1) of the first open region 151 of the first protective layer 150 may be smaller than a width of an upper surface of the first pad 120-1. For example, the first protective layer 150 may include a first open region 151 that covers at least a portion of an upper surface of the first pad 120-1 while exposing a remaining portion of an upper surface of the first pad 120-1.

At this time, the width (W1) of the first open region 151 of the first protective layer 150 may be 30 μm or less. Preferably, the width (W1) of the first open region 151 of the first protective layer 150 may be 28 μm or less. More preferably, the width (W1) of the first open region 151 of the first protective layer 150 may be 25 μm or less.

For example, the width (W1) of the first open region 151 of the first protective layer 150 may satisfy a range of 10 μm to 30 μm. Preferably, the width (W1) of the first open region 151 of the first protective layer 150 may satisfy a range of 12 μm to 28 μm. More preferably, the width (W1) of the first open region 151 of the first protective layer 150 may satisfy a range of 13 μm to 25 μm.

If the width (W1) of the first open region 151 of the first protective layer 150 is less than 10 μm, an amount of the solder ball or other connection part disposed in the first open region 151 is reduced, and thus the bonding strength with the semiconductor device may be reduced. If the width (W1) of the first open region 151 of the first protective layer 150 exceeds 30 μm, the width of the first pad 120-1 may increase accordingly, and thus the circuit integration may be reduced.

At this time, the first open region 151 of the first protective layer 150 in the first embodiment may have almost no change in width from a region adjacent to the upper surface of the first protective layer 150 to a region adjacent to the lower surface of the first protective layer 150. Here, a fact that there is almost no change in width may mean that a slope of a first inner surface 151S of the first protective layer 150 constituting the first open region 151 is close to vertical. For example, a fact that there is almost no change in width may mean that a difference in width between a region having a maximum width and a region having a minimum width in an entire region in the thickness direction of the first open region 151 is 3 μm or less, 2.5 μm or less, 2 μm or less, 1.5 μm or less, 1 μm or less, or 0.5 μm or less.

That is, the first open region 151 of the first protective layer 150 of the first embodiment does not include a region in which the width increases rapidly from an upper region to a lower region. In other words, a lower end of the first inner surface 151S of the first open region 151 of the first protective layer 150 of the first embodiment does not include an undercut.

This is because the first open region 151 of the first protective layer 150 is not formed by exposing and developing the first protective layer 150, but by using a separate resist pattern. That is, in the first embodiment, before forming the first protective layer 150, a first resist pattern (DFR1-F, see FIG. 6) corresponding to the first open region 151 is formed on the first pad 120-1. In addition, in the first embodiment, the first protective layer 150 is formed in a state where the first resist pattern DFR1-F is disposed. Accordingly, a first open region 151 corresponding to the first resist pattern DFR1-F is formed in the first protective layer 150.

Here, referring to FIG. 6, the first resist pattern DFR1-F can be formed using a photosensitive film. Accordingly, the photosensitive film can form a fine pattern compared to forming a pattern in a solder resist.

In the first embodiment, when the first protective layer 150 is formed while the first resist pattern DFR1-F is disposed, the first protective layer 150 entirely covers the first resist pattern DFR1-F. Thereafter, the first embodiment performs a process of thinning the first protective layer 150 to reduce a thickness of the first protective layer 150 to a target thickness. At this time, in a state where the first resist pattern DFR1-F is disposed, the first protective layer 150 may be made to have a target thickness without covering the first resist pattern DFR1-F. That is, in a state where the first resist pattern DFR1-F is disposed, the first protective layer 150 may be made to have a certain thickness without performing the thinning process. However, if the thinning process is not performed as described above, the first protective layer 150 may have a thickness deviation in a first region adjacent to the first resist pattern DFR1-F and a second region excluding the first region. For example, in a case where the thinning process is not performed as described above, a flatness of the upper surface 150T of the first protective layer 150 may deteriorate. Accordingly, the embodiment performs a process of thinning the first protective layer 150 to a target thickness while maintaining a certain thickness.

Therefore, an upper surface 150T of the first protective layer 150 of the first embodiment may have a surface roughness different from a surface roughness of the first inner surface 151S of the first open region 151.

That is, the upper surface 150T of the first protective layer 150 is a surface thinned by the thinning process. In contrast, the first inner surface 151S of the first open region 151 of the first protective layer 150 is a surface that has not been thinned. For example, the first inner surface 151S of the first open region 151 of the first protective layer 150 may correspond to a surface roughness of the first resist pattern DFR1-F.

In other words, the upper surface 150T of the first protective layer 150 may have a different roughness from the inner surface (150S, see FIG. 5) of the open region of the first protective layer 150. The inner surface 150S of the open region may include a first inner surface 151S of the first open region 151 and a second inner surface 152S of the second open region 152.

A surface roughness of the upper surface 150T of the first protective layer 150 may be greater than a surface roughness of the inner surface of the open region of the first protective layer 150.

That is, referring to FIG. 4, the first protective layer 150 includes a resin and a filler 150F dispersed within the resin. At this time, when the first protective layer 150 is thinned, the filler 150F disposed in the first protective layer 150 may be exposed to the upper surface 150T of the first protective layer 150 due to the thinning. In contrast, the filler 150F may not be exposed to the inner surface 150S of the open region of the first protective layer 150, or a smaller amount of filler may be exposed than the amount of filler exposed to the upper surface 150T. Accordingly, the upper surface 150T of the first protective layer 150 may have a greater surface roughness than the inner surface of the open region of the first protective layer 150 due to the filler 150F. Preferably, the filler 150F may not be exposed to the inner surface 150S of the open region of the first protective layer 150.

Meanwhile, the filler 150F may be exposed entirely on the upper surface 150T of the first protective layer 150. That is, the embodiment performs thinning on the entire region of the surface of the first protective layer 150. Accordingly, the entire region of the upper surface 150T of the first protective layer 150 may be a thinned surface. Accordingly, the filler 150F may be exposed entirely on the upper surface 150T of the first protective layer 150. In addition, the embodiment may increase the surface roughness of the upper surface 150T of the first protective layer 150 using the filler 150F exposed through the upper surface 150T of the first protective layer 150. Through this, the embodiment can increase a bonding area between the first protective layer 150 and the molding layer in a molding process after mounting the semiconductor device on the circuit board, thereby improving the bonding strength.

Meanwhile, the first protective layer 150 includes a second open region 152. For example, the first protective layer 150 can include a second open region 152 that vertically overlaps the second pad 120-2 of the first circuit pattern layer 120.

At this time, the second open region 152 of the first protective layer 150 can vertically overlap the upper surface of the second pad 120-2 as a whole. For example, the second open region 152 of the first protective layer 150 can be an open region of a NSMD type.

That is, a width (W2) of the second open region 152 of the first protective layer 150 may be larger than a width of an upper surface of the second pad 120-2. For example, the first protective layer 150 may entirely expose an upper surface and an inner surface of the second pad 120-2. For example, a second inner surface 152S of the second open region 152 of the first protective layer 150 may be spaced apart from and not in contact with the second pad 120-2. For example, the second pad 120-2 may not be in contact with the first protective layer 150.

At this time, a width (W2) of the second open region 152 of the first protective layer 150 may be 30 μm or less. Preferably, the width (W2) of the second open region 152 of the first protective layer 150 may be 28 μm or less. More preferably, the width (W2) of the second open region 152 of the first protective layer 150 may be 25 μm or less.

For example, the width (W2) of the second open region 152 of the first protective layer 150 may satisfy a range of 10 μm to 30 μm. Preferably, the width (W2) of the second open region 152 of the first protective layer 150 may satisfy a range of 12 μm to 28 μm. More preferably, the width (W2) of the second open region 152 of the first protective layer 150 may satisfy a range of 13 μm to 25 μm.

If the width (W2) of the second open region 152 of the first protective layer 150 is less than 10 μm, the amount of a connection part such as a solder ball placed in the second open region 152 is reduced, and thus the bonding strength with the semiconductor device may be reduced. If the width (W2) of the second open region 152 of the first protective layer 150 exceeds 30 μm, a distance between the second pad 120-2 and a circuit pattern (e.g., trace) adjacent to the second pad increases, and thus the circuit integration may be reduced.

At this time, the second open region 152 of the first protective layer 150 in the first embodiment may have almost no change in width from a region adjacent to an upper surface of the first protective layer 150 to a region adjacent to a lower surface of the first protective layer 150. For example, a slope of the second inner surface 152S of the first protective layer 150 constituting the second open region 152 may be close to vertical. For example, a difference in width between a region having a maximum width and a region having a minimum width in the entire region in the thickness direction of the second open region 152 may be 3 μm or less, 2.5 μm or less, 2 μm or less, 1.5 μm or less, 1 μm or less, or 0.5 μm or less.

That is, the second open region 152 of the first protective layer 150 of the first embodiment does not include a region whose width increases rapidly from an upper region to a lower region. In other words, a lower end of the second inner surface 152S of the second open region 152 of the first protective layer 150 of the first embodiment does not include an undercut.

That is, in the first embodiment, before forming the first protective layer 150, a resist pattern DFR1-F can also be formed in a region where the second open region 152 is to be formed to correspond to the first open region 151. Through this, the second open region 152 can be formed in the first protective layer 150 corresponding to the resist pattern DFR1-F.

In addition, a second inner surface 152S of the second open region 152 is also a surface on which thinning has not been performed. Accordingly, a surface roughness of the second inner surface 152S of the second open region 152 may be smaller than a surface roughness of the upper surface 150T of the first protective layer 150.

As described above, the first protective layer 150 in the first embodiment includes an open region. At this time, the open region may be formed in the first protective layer 150 using a separate resist pattern DFR1-F.

At this time, the resist pattern DFR1-F may be a photosensitive film (DFR: Dry Film Photoresist). At this time, the photosensitive film does not include a filler therein. Accordingly, a minimum size of the resist pattern formed by exposing and developing the photosensitive film is generally smaller than a resist pattern formed by exposing and developing a solder resist including a filler.

Accordingly, the embodiment does not expose and develop the protective layer itself, such as the solder resist, but rather exposes and develops a photosensitive film capable of implementing a relatively fine pattern to form a resist pattern. In addition, the embodiment forms an open region in the first protective layer 150 using the resist pattern. Therefore, the embodiment can reduce a size of the open region formed in the first protective layer 150 compared to the comparative example, thereby improving the circuit integration.

At this time, since the embodiment does not expose and develop the first protective layer 150, the first protective layer 150 does not need to contain a photo initiator. For example, a general solder resist contains a photo initiator for exposure and development. At this time, the photo initiator acts as a factor that deteriorates the physical characteristics and electrical characteristics of the circuit board.

Here, since the embodiment does not expose and develop the first protective layer 150, the first protective layer 150 does not contain a photo initiator. Accordingly, the embodiment can improve the physical characteristics and electrical characteristics of the circuit board since the first protective layer 150 does not include a photo initiator.

Furthermore, the embodiment can expand a types of insulating layers that can be used as the first protective layer 150 since the first protective layer 150 does not include a photo initiator, and further reduce an unit cost required for developing the protective layer.

For example, the first protective layer 150 of the embodiment can be a solder resist without a photo initiator. Differently, the first protective layer 150 of the embodiment can use an insulating layer in which an inorganic filler of silica or alumina is disposed in a thermosetting resin or a thermoplastic resin without including glass fibers. For example, the first protective layer 150 can use ABF (Ajinomoto Build-up Film), FR-4, BT (Bismaleimide Triazine), PID (Photo Imageable Dielectric resin), BT, etc.

However, according to an embodiment, the first protective layer 150 and the second protective layer 160 of the present invention may be implemented by using a solder resist used in a general circuit board. For example, according to an embodiment, the first protective layer 150 and the second protective layer 160 may include a photo initiator.

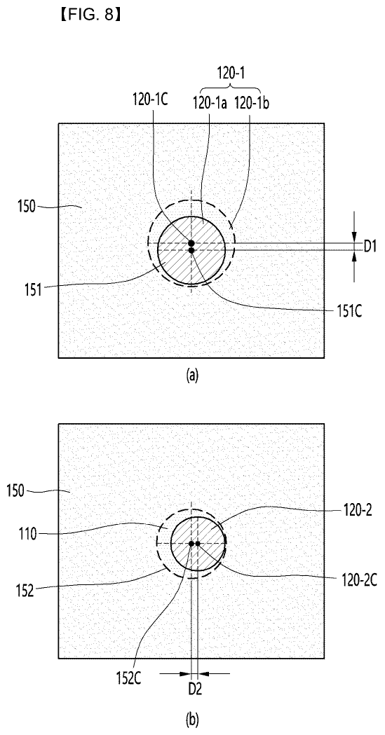

FIG. 7 is a plan view for explaining a tolerance (SRR: Solder Resist Registration) according to a comparative example, and FIG. 8 is a view for explaining a tolerance according to a first embodiment.

Referring to FIG. 7 (a), in a case of the comparative example, the first pad 21 includes a first portion 21a exposed through the first open region 31 of the protective layer 30 and a second portion 21b covered with the protective layer 30. At this time, in the comparative example, the protective layer 30 is exposed and developed in order to form the first open region 31. At this time, the protective layer 30 has a significantly lower exposure resolution than the DFR. Accordingly, in the comparative example, it can be confirmed that a center 21C of the first pad 21 and a center 31C of the first open region 31 are misaligned by a first tolerance (d1). Specifically, the first tolerance (d1) between the center 21C of the first pad 21 and the center 31C of the first open region 31 in the comparative example exceeds 12.5 um, or exceeds 14 um, or exceeds 15 um. Accordingly, in the comparative example, an alignment reliability problem may occur in which at least a part of the first open region 31 does not vertically overlap with the first pad 21.

Referring to (b) of FIG. 7, in the comparative example, the second pad 22 is entirely exposed through the second open region 32 of the protective layer 30. At this time, in the comparative example, in order to form the second open region 32, the protective layer 30 is exposed and developed. At this time, the protective layer 30 has a significantly lower exposure resolution than the DFR. Accordingly, in the comparative example, it can be confirmed that a center 22C of the second pad 22 and a center 32C of the second open region 32 are misaligned by a second tolerance (d2). Specifically, the second tolerance (d2) between the center 22C of the second pad 22 and the center 32C of the second open region 32 in the comparative example exceeds 12.5 μm, or exceeds 14 μm, or exceeds 15 μm. Accordingly, in the comparative example, an alignment reliability problem may occur in which at least a portion of the upper surface of the second pad 22 is covered by the protective layer 30.

In contrast, the embodiment can significantly reduce a tolerance compared to the comparative example.

For example, referring to (a) of FIG. 8, in the case of the embodiment, the first pad 120-1 includes a first portion 120-1a exposed through the first open region 151 of the first protective layer 150 and a second portion 120-1b covered with the first protective layer 150. At this time, in the embodiment, instead of exposing and developing the first protective layer 150, a resist pattern DFR1-F formed by DFR is used to form the first open region 151. Accordingly, in the embodiment, it can be confirmed that a center 120-1C of the first pad 120-1 and a center 151C of the first open region 151 are misaligned by a third tolerance (D1) that is significantly reduced compared to the first tolerance (d1) of the comparative example. Specifically, the third tolerance (D1) between the center 120-1C of the first pad 120-1 and the center 151C of the first open region 151 of the embodiment is 10 μm or less, or 9 μm or less, or 8 μm or less. Therefore, the embodiment can improve the alignment accuracy between the first open region 151 and the first pad 120-1. Through this, the embodiment can further improve the electrical reliability and/or physical reliability of the circuit board.

In addition, referring to (b) of FIG. 8, in the case of the embodiment, the second pad 120-2 is entirely exposed through the second open region 152 of the first protective layer 150. At this time, in the embodiment, in order to form the second open region 152, instead of exposing and developing the first protective layer 150, a resist pattern DFR1-F formed by DFR is used. Accordingly, in the embodiment, it can be confirmed that a center 120-2C of the second pad 120-2 and a center 152C of the second open region 152 are misaligned by a fourth tolerance (D2) that is significantly reduced compared to the second tolerance (d2) of the comparative example. Specifically, the fourth tolerance (D2) between the center 120-1C of the second pad 120-2 and the center 152C of the second open region 152 of the embodiment is 10 μm or less, or 9 μm or less, or 8 μm or less. Therefore, the embodiment can improve the alignment accuracy between the second open region 152 and the second pad 120-2. Through this, the embodiment can further improve the electrical reliability and/or the physical reliability of the circuit board.

The embodiment includes an insulating layer, a pad disposed on the insulating layer, and a protective layer disposed on the insulating layer and including an open region overlapping the pad in a vertical direction.

In this case, a width of the open region of the protective layer of the embodiment is 30 μm or less. For example, the width of the open region of the protective layer of the embodiment may satisfy a range of 10 μm to 30 μm, 12 μm to 28 μm, or 13 μm to 25 μm.

Furthermore, the open region of the protective layer of the embodiment has little change in width toward a thickness direction. For example, in an entire region in a thickness direction of the open region of the embodiment, the difference between a width of a region having a maximum width and a region having a minimum width may be 3 μm or less, 2.5 μm or less, 2 μm or less, 1.5 μm or less, 1 μm or less, or 0.5 μm or less. That is, in an embodiment, an undercut at a lower end of the inner surface of the open region of the protective layer may be removed, or a horizontal distance of an undercut may be significantly reduced compared to a comparative example.

This is because the open region of the protective layer is not formed by exposing and developing the protective layer, but a separate resist pattern is used. That is, in an embodiment, the protective layer is disposed in a state in which a resist pattern is formed using a photosensitive film. Accordingly, an open region corresponding to the resist pattern may be formed in the protective layer. In this case, the photosensitive film does not include a filler therein. Accordingly, in general, a minimum size of a resist pattern formed by exposing and developing the photosensitive film is smaller than that of a resist pattern formed by exposing and developing a solder resist containing a filler.

Accordingly, an embodiment does not expose and develop a protective layer such as a solder resist, but rather exposes and develops a photosensitive film capable of implementing a relatively fine pattern to form a resist pattern. Then, an embodiment forms an open region in the protective layer by using the resist pattern. Accordingly, an embodiment may reduce a size of the open region formed on the protective layer compared to a comparative example, thereby improving the circuit integration.

Furthermore, since the embodiment does not expose and develop the protective layer, and it is possible to remove undercuts that may be formed at the inner surface of the open region of the protective layer. Accordingly, the embodiment may further reduce a spacing between circuit pattern layers.

Meanwhile, in the embodiment, in a state in which the resist pattern is disposed, a thickness of the protective layer is made larger than that of the resist pattern and then a process of thinning the protective layer is performed. That is, in the embodiment, the protective layer may have a target thickness through the thinning. In this case, a process of applying the protective layer to have a target thickness may be performed without proceeding with the thinning process. However, if the thinning process is not performed, there is a problem that a thickness deviation of the protective layer increases, and accordingly, a flatness of the protective layer decreases.

On the other hand, since the embodiment performs the thinning process, the flatness of the protective layer may be improved. Accordingly, the embodiment may improve overall physical reliability and electrical reliability of the circuit board and the semiconductor package.

In addition, the filler may be entirely exposed on the upper surface of the protective layer of the embodiment. In addition, the exposed filler increases a surface roughness of the upper surface of the protective layer. Accordingly, the embodiment may increase a bonding area between the protective layer and the molding layer in a molding process after the semiconductor device is mounted on a circuit board, thereby improving bonding strength. Accordingly, the embodiment may further improve product reliability.

Meanwhile, in an embodiment, since the protective layer is not exposed and developed, a photo initiator is not required in the protective layer. For example, a general solder resist contains a photo initiator for exposure and development. In this case, the photo initiator acts as a factor that deteriorates physical and electrical characteristics of the circuit board. In this case, an embodiment may improve physical and electrical characteristics of the circuit board since a photo initiator is not included in the protective layer.

Furthermore, since the embodiment does not include a photo initiator in the protective layer, a type of insulating layer that can be used as the protective layer can be expanded, and furthermore, an unit price required for the development of the protective layer can be reduced.

Furthermore, an embodiment may significantly reduce a tolerance between a center of the open region of the protective layer and a center of the pad compared to the comparative example. Accordingly, an embodiment may improve mount-ability of a semiconductor device, thereby improving the physical reliability and electrical reliability of the circuit board and the semiconductor package.

FIG. 9 is a cross-sectional view showing a circuit board according to a second embodiment.

The circuit board according to the second embodiment will be described with reference to FIG. 9.

The circuit board of the second embodiment includes an insulating layer 210.

In addition, the circuit board of the second embodiment includes a first circuit pattern layer 220 disposed on the insulating layer 210. In addition, the circuit board of the second embodiment includes a second circuit pattern layer 230 disposed under the insulating layer 210. In addition, the circuit board of the second embodiment includes a through electrode 240 penetrating the insulating layer 210. In addition, the circuit board of the second embodiment includes a first protective layer 250 disposed on the insulating layer 210. In addition, the circuit board of the second embodiment includes a second protective layer 260 disposed under the insulating layer 210.

The first circuit pattern layer 220, the second circuit pattern layer 230, and the through electrode 240 each include a first metal layer 221, 231, and 241 and a second metal layer 222, 232, and 242.

The first protective layer 250 and the second protective layer 260 each include at least one open region.

At this time, the circuit board of the second embodiment has a difference in open regions formed in the first protective layer 250 and the second protective layer 260 compared to the circuit board of the first embodiment.

Accordingly, a following description will focus on an open region formed in the first protective layer 250.

An inner surface of the open region in the first embodiment has a substantially vertical slope with respect to the upper surface of the insulating layer.

Unlike this, an inner surface of an open region in the second embodiment may have a slope with respect to the upper surface of the insulating layer.

For example, the first circuit pattern layer 220 includes a first pad 220-1 and a second pad 220-2. In addition, the first protective layer 250 includes a first open region 251 that vertically overlaps the first pad 220-1. In addition, the first protective layer 250 includes a second open region 252 that vertically overlaps the second pad 220-2.

At this time, basic structures of the first open region 251 and the second open region 252 are the same as those of the first embodiment, and a detailed description thereof is omitted.

A width of the first open region 251 may change from an upper surface of the first protective layer 250 to a lower surface of the first protective layer 250. For example, a first inner surface 251S of the first protective layer 250 of the first protective layer 250 may have a slope whose width decreases toward a downward direction. That is, in the second embodiment, a photosensitive film used to form the first open region 251 is a negative type, and a resist pattern DFR1-F may be formed using the negative type photosensitive film. Through this, the resist pattern DFR1-F may have a shape whose width decreases toward the downward direction. In addition, a first inner surface 251S of the first open region 251 of the first protective layer 250 formed by the resist pattern DFR1-F may have a slope whose width decreases toward the downward direction. The negative type photosensitive film has a characteristic in which a portion that is not exposed to light is developed and removed during exposure and development.

Correspondingly, a second inner surface 252S of the second open region 252 of the first protective layer 250 may also have a slope in which the width decreases toward the downward direction.

At this time, in the embodiment, the first inner surface 251S and the second inner surface 252S do not include an undercut. Accordingly, each of the first inner surface 251S and the second inner surface 252S has a slope in which the width decreases from an upper end toward a lower end. At this time, the first open region 251 and the second open region 252 only include a slope in which the width decreases from an upper end toward a lower end of the first inner surface 251S and the second inner surface 252S, respectively, and do not include a slope in which the width is maintained or a slope in which the width increases. In other words, the slope in which the width is maintained or the slope in which the width increases may mean an undercut. In addition, since the embodiment does not include an undercut, each of the first inner surface 251S and the second inner surface 252S of the first open region 251 and the second open region 252 may include only a slope in which the width decreases, and may not include a slope in which the width is maintained or the width increases.

At this time, the embodiment forms an open region in the first protective layer 250 using a negative type photosensitive film as described above. Through this, the embodiment can ensure that the removal of the resist pattern DFR1-F is smoothly performed in the process of removing the resist pattern DFR1-F after forming the open region in the first protective layer 250. Through this, the embodiment can solve the problem of the first protective layer 250 being separated from the insulating layer 210 in a process of removing the resist pattern DFR1-F.

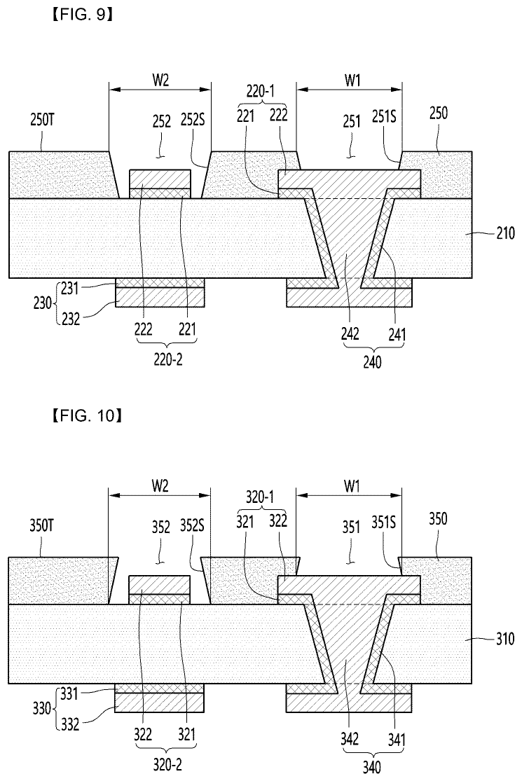

FIG. 10 is a cross-sectional view showing a circuit board according to the third embodiment.

A circuit board according to a third embodiment will be described with reference to FIG. 10.

The circuit board of the third embodiment includes an insulating layer 310.

In addition, the circuit board of the third embodiment includes a first circuit pattern layer 320 disposed on the insulating layer 310. In addition, the circuit board of the third embodiment includes a second circuit pattern layer 330 disposed under the insulating layer 310. In addition, the circuit board of the third embodiment includes a through electrode 340 penetrating the insulating layer 310. In addition, the circuit board of the third embodiment includes a first protective layer 350 disposed on the insulating layer 310. In addition, the circuit board of the third embodiment includes a second protective layer 360 disposed under the insulating layer 310.

The first circuit pattern layer 320, the second circuit pattern layer 330, and the through electrode 340 each include a first metal layer 321, 331, and 341 and a second metal layer 322, 332, and 342.

The first protective layer 350 and the second protective layer 360 each include at least one open region.

At this time, the circuit board of the third embodiment has a difference in open regions formed in the first protective layer 350 and the second protective layer 360 compared to the circuit board of the first embodiment.

Accordingly, a following description will focus on the open region formed in the first protective layer 350.

The inner surface of the open region in the first embodiment had a slope that was substantially perpendicular to the upper surface of the insulating layer, and the inner surface of the open region in the second embodiment had a slope that decreased in width toward a downward direction.

In contrast, an inner surface of the open region of the third embodiment may have a slope whose width increases toward the downward direction.

For example, the first circuit pattern layer 320 includes a first pad 320-1 and a second pad 320-2. In addition, the first protective layer 350 includes a first open region 351 that vertically overlaps the first pad 320-1. In addition, the first protective layer 350 includes a second open region 352 that vertically overlaps the second pad 320-2.

At this time, basic structures of the first open region 351 and the second open region 352 is the same as that of the first embodiment, and a detailed description thereof is omitted.

A width of the first open region 351 may change from the upper surface of the first protective layer 350 to the lower surface. For example, a first inner surface 351S of the first open region 351 of the first protective layer 350 may have a slope whose width increases toward the downward direction. That is, in the third embodiment, a photosensitive film used to form the first open region 351 is a positive type, and the resist pattern DFR1-F may be formed using the positive type photosensitive film. Through this, the resist pattern DFR1-F may have a shape whose width increases toward the downward direction. In addition, the first inner surface 351S of the first open region 351 of the first protective layer 350 formed by the resist pattern DFR1-F may have a slope whose width increases toward the downward direction. The positive type photosensitive film has a characteristic in which a portion that has received light is developed and removed during exposure and development.

Correspondingly, a second inner surface 352S of the second open region 352 of the first protective layer 350 may also have a slope whose width decreases toward the downward direction. At this time, in the third embodiment, as the width of the open region increases toward the downward direction, when a connecting part such as a solder ball is placed in the open region, the open region may function as an anchor. Through this, the embodiment may improve the bonding characteristic with the connecting part.

### Semiconductor Package

FIG. 11 is a cross-sectional view showing a semiconductor package according to the embodiment.

Referring to FIG. 11, a semiconductor package of an embodiment may include any one of the circuit boards illustrated in FIG. 2, FIG. 9, and FIG. 10. In addition, the circuit board may have a multilayer structure.

The semiconductor package of the embodiment includes a first connection part 410. That is, the circuit pattern layer of the circuit pattern includes pads disposed to correspond to a mounting region of the semiconductor device 420. The pad may mean a first pad of the first circuit pattern layer, or, differently, may mean a second pad of the first circuit pattern layer.

The first connection part 410 may have a hexahedral shape. A cross-section of the first connection part 410 may include a square shape. The cross-section of the first connection part 410 may include a rectangle or a square. For example, the first connection part 410 may include a spherical shape. For example, the cross-section of the first connection part 410 may include a circular shape or a semicircular shape. For example, the cross-section of the first connection part 410 may include a partially or entirely rounded shape. A cross-section shape of the first connection part 410 may be flat at one side and curved at the other side. The first connection part 410 may be a solder ball, but is not limited thereto.

The semiconductor package of the embodiment includes a component disposed on the first connection part 410. The component disposed on the first connection part 410 may be a semiconductor device, or alternatively, an interposer. Hereinafter, the component disposed on the first connection part 410 will be described as a semiconductor device 420.

The semiconductor device 420 may be a logic chip, but is not limited thereto. For example, the semiconductor device 420 may be an application processor (AP) chip among a central processor (e.g., a CPU), a graphic processor (e.g., a GPU), a digital signal processor, an encryption processor, a microprocessor, and a microcontroller. The semiconductor device 420 includes a terminal 425 provided at a lower surface of the semiconductor device 420. In addition, the terminal 425 of the semiconductor device 420 is connected to the circuit pattern layer of the circuit board through the first connection part 410.

In addition, the semiconductor package may include an underfill 430. The underfill 430 may be disposed to cover a periphery of the semiconductor device 420 on the circuit board. However, the underfill 430 may be optionally omitted. For example, the semiconductor package may perform a function of the underfill 430 in the molding layer 450 while the underfill 430 is omitted.

The semiconductor package may include a second connection part 440. The second connection part 440 is disposed on the circuit pattern layer of the circuit board.

The second connection part 440 may be a bump. For example, the second connection part 440 may be a solder bump, but is not limited thereto. For example, the second connection part 440 may be a post bump. For example, the second connection part 440 may include a copper post and a solder bump disposed on the copper post. An upper surface of the second connection part 440 may be positioned higher than an upper surface of the semiconductor device 420. Accordingly, the semiconductor device 420 may be prevented from being damaged during a bonding process of an external substrate 500 disposed on the second connection part 440.

The semiconductor package may include a molding layer 450. The molding layer 450 may mold the components disposed on the circuit board.

The molding layer 450 may be an EMC (Epoxy Mold Compound), but is not limited thereto. The molding layer 450 may have a low permittivity. For example, the permittivity (Dk) of the molding layer 450 may be 0.2 to 10. For example, the permittivity (Dk) of the molding layer 450 may be 0.5 to 8. For example, the permittivity (Dk) of the molding layer 450 may be 0.8 to 5. Accordingly, in the embodiment, the molding layer 450 may have a low permittivity, thereby improving the heat dissipation characteristics of heat generated from the semiconductor device 420. The molding layer 450 may include an opening. For example, the molding layer 450 may include an opening that overlaps the upper surface of the second connection part 440 in a vertical direction.

The semiconductor package includes a third connection part 460.

The third connection part 460 may be disposed under the circuit pattern layer disposed at a lowest side of the circuit board. The third connection part 460 may be a solder for connecting the semiconductor package of the embodiment to a separate external substrate (e.g., a main board of an electronic device), but is not limited thereto.

The semiconductor package includes an external substrate 500. The external substrate 500 may mean a separate substrate combined with the circuit board of the embodiment. For example, the semiconductor device 420 disposed on the circuit board may be a logic chip such as a CPU or GPU, and the external substrate 500 may mean a memory substrate on which a memory chip connected to the logic chip is disposed. The external substrate 500 may be an interposer that connects between the memory substrate on which the semiconductor device 420 corresponding to the memory chip is disposed and the circuit board.

The external substrate 500 may include an insulating layer 510, a circuit layer 520, a through electrode 530, an upper protective layer 540, and a lower protective layer 550. In addition, the external substrate 500 may include a fourth connection part 560. The fourth connection part 560 may be disposed between the external substrate 500 and the third connection part 440.

In addition, the semiconductor package may include a fifth connection part 570. The fifth connection part 570 may be disposed on the external substrate 500.

The semiconductor package may include a semiconductor device 580. The semiconductor device 580 may be mounted on the external substrate 500 through the fifth connection part 570. The semiconductor device 580 may be a memory chip, but is not limited thereto. A terminal 585 of the semiconductor device 580 may be electrically connected to the external substrate 500 through the fifth connection part 570. At this time, the semiconductor device 580 is illustrated as being mounted in a flip chip manner, but is not limited thereto. The semiconductor device 580 may be a stack memory chip, and accordingly, may be electrically connected to the external substrate 500 through a separate connecting member such as a wire.

### Manufacturing Method

Hereinafter, a method for manufacturing a circuit board according to an embodiment will be described.

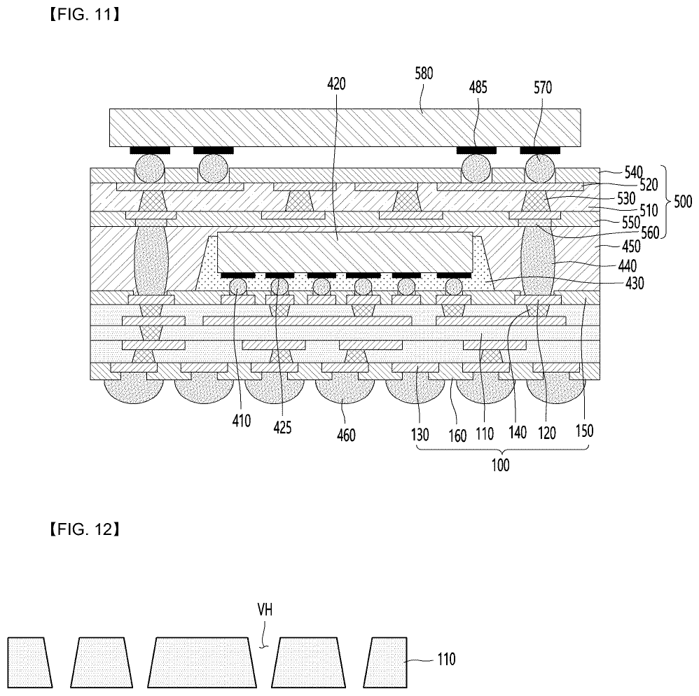

FIGS. 12 to 19 are cross-sectional views showing a method for manufacturing a circuit board according to an embodiment in order of processes.

Referring to FIG. 12, in the embodiment, an insulating layer 110 is prepared.

Thereafter, the embodiment forms a through hole VH penetrating an upper surface and a lower surface of the insulating layer 110.

Next, referring to FIG. 13, the embodiment can form a through electrode 140 filling the through hole VH on the insulating layer 110. In addition, the embodiment can form a first circuit pattern layer 120 including a first pad 120-1 and a second pad 120-2 on the upper surface of the insulating layer 110. In addition, the embodiment can form a second circuit pattern layer 130 on the lower surface of the insulating layer 120.

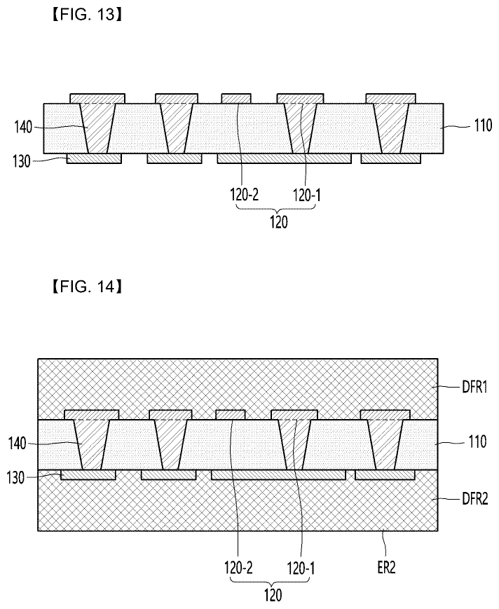

Thereafter, referring to FIG. 14, the embodiment forms a first dry film DFR1 on the insulating layer 120. At this time, the first dry film DFR1 can be disposed to entirely cover the first circuit pattern layer 120.

In addition, the embodiment forms a second dry film DFR2 under the insulating layer 120. At this time, the second dry film DFR2 may be disposed to entirely cover the second circuit pattern layer 130.

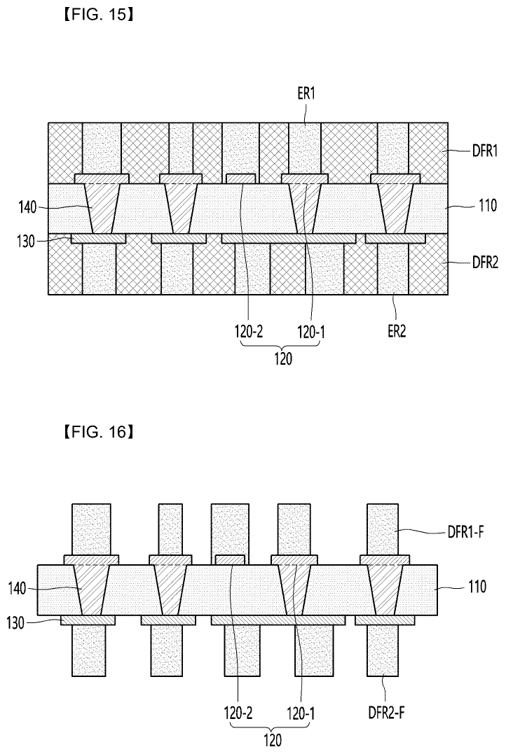

Next, referring to FIG. 15, the embodiment can perform a process of forming a first exposure pattern ER1 by exposing and curing the first dry film DFR1. At this time, the first dry film DFR1 may be a negative type. Accordingly, a portion that has not been exposed to light may be removed by subsequent development, and a first exposure pattern ER1 that has been exposed to light may not be removed.

In addition, the embodiment may perform a process of forming a second exposure pattern ER2 by exposing and curing the second dry film DFR2. At this time, the second dry film DFR2 may be a negative type. Accordingly, a portion that has not been exposed to light is removed by subsequent development, and a second exposure pattern ER2 that has been exposed to light may not be removed.

Next, referring to FIG. 16, the embodiment may perform a process of forming a first resist pattern DFR1-F by removing a region excluding the first exposure pattern ER1 from the first dry film DFR1. At this time, the first resist pattern DFR1-F may be formed to correspond to a region where the open region of the first protective layer 150 is to be formed on the insulating layer 120.

In addition, the embodiment may perform a process of forming a second resist pattern DFR2-F by removing a region excluding the second exposure pattern ER2 from the second dry film DFR2. At this time, the second resist pattern DFR2-F may be formed corresponding to a region where the open region of the second protective layer 160 is to be formed on the insulating layer 120.

Next, referring to FIG. 17, the embodiment may form a first protective layer 150R covering the first resist pattern DFR1-F on the insulating layer 120. In addition, the embodiment may form a second protective layer 160R covering the second resist pattern DFR2-F under the insulating layer 120.

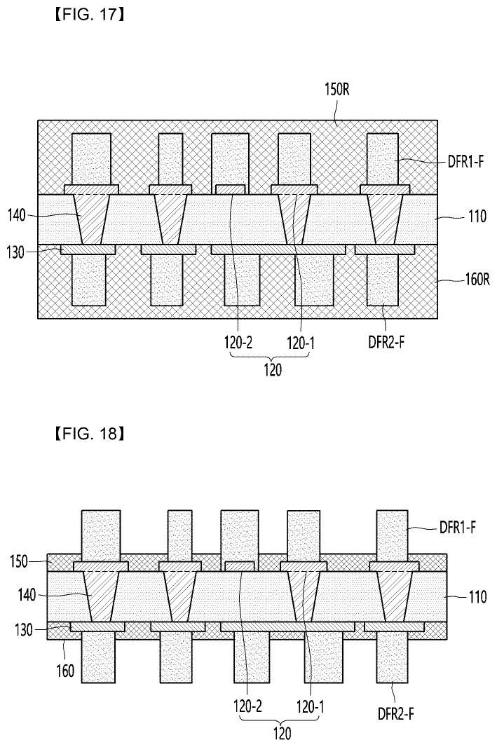

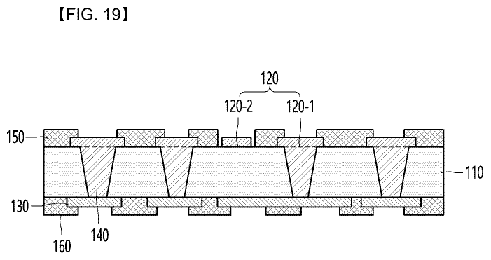

Next, referring to FIG. 18, the embodiment can perform a process of reducing a thickness of the first protective layer 150R to a target thickness by removing the first protective layer 150R by thinning.

The thinning process can be performed using an organic alkaline compound containing tetramethylammonium hydroxide (TMAH) or trimethyl-2-hydroxyethylammonium hydroxide (choline).

In addition, the embodiment can perform a process of reducing a thickness of the second protective layer 160R to a target thickness by removing the second protective layer 160R by thinning.

Next, referring to FIG. 19, the embodiment can perform a process of removing the first resist pattern DFR1-F and the second resist pattern DFR2-F. As a result, the embodiment can form open regions in the first protective layer 150 and the second protective layer 160 respectively corresponding to the first resist pattern DFR1-F and the second resist pattern DFR2-F.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1-10. (canceled)

11. A circuit board comprising:
an insulating layer including an upper surface and a lower surface;
a circuit pattern layer disposed on the upper surface of the insulating layer;
a protective layer disposed on the circuit pattern layer and including an open region overlapping the circuit pattern layer along a vertical direction; and
a through electrode passing through at least a portion of the insulating layer from the upper surface to the lower surface and disposed closest to the protective layer,
wherein a slope of an inner wall of the open region with respect to the upper surface of the insulating layer is closer to a right angle than a slope of a side surface of the through electrode with respect to the upper surface of the insulating layer.

12. The circuit board of claim 11, wherein the protective layer includes a plurality of fillers, and
wherein the plurality of fillers are spaced apart from the inner wall of the open region within the protective layer.

13. The circuit board of claim 12, wherein at least one of the plurality of fillers is positioned higher than an upper surface of the protective layer.

14. The circuit board of claim 11, wherein the slope of the inner wall of the open region changes toward the upper surface of the insulating layer.

15. The circuit board of claim 14, wherein a difference between a maximum width and a minimum width of the open region in a horizontal direction along the vertical direction is smaller than a difference between a width of an upper surface of the through electrode in the horizontal direction and a width of a lower surface of the through electrode in the horizontal direction.

16. The circuit board of claim 15, wherein the difference between the maximum width and the minimum width of the open region in the horizontal direction along the vertical direction is 3 μm or less.

17. The circuit board of claim 11, wherein the circuit pattern layer includes a first wiring portion and a second wiring portion spaced apart along the horizontal direction,
wherein the open region includes a first open region overlapping the first wiring portion along the vertical direction, and a second open region overlapping the second wiring portion along the vertical direction,
wherein a width of the first open region in the horizontal direction is smaller than a width of the first wiring portion in the horizontal direction, and
wherein a width of the second open region in the horizontal direction is larger than a width of the second wiring portion in the horizontal direction.

18. The circuit board of claim 17, wherein the width of the first open region in the horizontal direction and the width of the second open region in the horizontal direction are same.

19. The circuit board of claim 17, wherein a center of the first open region in the horizontal direction and a center of the first wiring portion in the horizontal direction are misaligned.

20. The circuit board of claim 19, wherein a width in the horizontal between the center of the first open region and the center of the first wiring portion is 10 μm or less.

21. The circuit board of claim 11, wherein a surface roughness of an upper surface of the protective layer is greater than a surface roughness of the inner wall of the open region of the protective layer.

22. A method for manufacturing a circuit board comprising:
preparing an insulating layer;
forming a through electrode passing through at least a portion of the insulating layer along a vertical direction, and a circuit pattern layer disposed on the through electrode;
disposing a resist film covering the circuit pattern layer on the insulating layer;
patterning the resist film to form a resist pattern overlapping the circuit pattern layer along the vertical direction;
disposing a protective layer on the insulating layer while the resist pattern is disposed; and
removing the resist pattern to form an open region in the protective layer corresponding to a position where the resist pattern is removed.

23. The method of claim 22, wherein the disposing of the protective layer comprises reducing a thickness of the protective layer so that an upper surface of the protective layer is positioned lower than an upper surface of the resist pattern while the protective layer covers the resist pattern.

24. The method of claim 23, wherein a width in a horizontal direction of the open region of the protective layer is 30 μm, and
wherein a slope of an inner wall of the open region with respect to an upper surface of the insulating layer is closer to a right angle than a slope of a side surface of the through electrode with respect to the upper surface of the insulating layer.

25. The method of claim 24, wherein the protective layer includes a plurality of fillers,
wherein the plurality of fillers are spaced apart from the inner wall of the open region within the protective layer, and
wherein at least one of the plurality of fillers is positioned higher than the upper surface of the protective layer.

26. The method of claim 23, wherein a slope of an inner wall of the open region changes toward the upper surface of the insulating layer.

27. The method of claim 26, wherein a difference between a maximum width and a minimum width of the open region in a horizontal direction along a vertical direction is smaller than a difference between a width of an upper surface of the through electrode in the horizontal direction and a width of a lower surface of the through electrode in the horizontal direction.

28. The method of claim 27, wherein the difference between the maximum width and the minimum width of the open region in the horizontal direction along the vertical direction is 3 μm or less.

29. The method of claim 23, wherein the circuit pattern layer includes a first wiring portion and a second wiring portion spaced apart along a horizontal direction, and
wherein the forming of the resist pattern comprises:
forming a first resist pattern having a width smaller than a width of the first wiring portion on the first wiring portion, and
forming a second resist pattern having a width larger than a width of the second wiring portion on the second wiring portion.

30. The method of claim 17, wherein a center of the first open region in the horizontal direction is misaligned with a center of the first wiring portion in the horizontal direction, and
wherein a width in the horizontal direction between the center of the first open region and the center of the first wiring portion is 10 μm or less.
